(19) United States
(12) Patent Application Publication
(10) Pub. No.: US 2026/0324493 A1
(43) Pub. Date: Oct. 15, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Shimon AJISAKA, Tokyo (JP); Naoto KAGUCHI, Tokyo (JP); Tomohito KUDO, Tokyo (JP)

(73) Assignee: Mitsubishi Electric Corporation, Tokyo (JP)

(21) Appl. No.: 19/109,322

(22) PCT Filed: Nov. 11, 2022
(86) PCT No.: PCT/JP2022/042048

§ 371 Date: Mar. 6, 2025

(51) Int. Cl. H10W 74/10; H10D 8/00; H10D 8/01; H10P 58/00; H10W 74/01

(52) U.S. Cl. CPC H10W 74/121; H10P 58/00; H10W 74/016; H10W 74/127; H10D 8/045; H10D 8/411

(57) ABSTRACT

A semiconductor device includes: a semiconductor substrate in which a semiconductor element is formed; a front surface electrode formed on a first main surface of the semiconductor substrate; a back surface electrode formed on a second main surface of the semiconductor substrate; and a surface protection film formed on the first main surface of the semiconductor substrate to cover the front surface electrode and having an opening part exposing a part of the front surface electrode. An upper surface of the surface protection film is roughened by a cutting mark.

### TECHNICAL FIELD

The present disclosure relates to a semiconductor device and a method of manufacturing the semiconductor device.

### BACKGROUND ART

Known is a semiconductor device having a surface on which a surface protection film made up of polyimide resin, for example, is formed. For example, Patent Document 1 described hereinafter discloses a technique of non-flattening (referred to as “roughening” hereinafter) an upper surface of the surface protection film by sputtering processing.

### PRIOR ART DOCUMENTS

### Patent Document(s)

Patent Document 1: Japanese Patent Application Laid-Open No. 2007-158113

### SUMMARY

### Problem to be Solved by the Invention

In a case where a semiconductor device including a surface protection film is mounted to a resin mold package, if adhesiveness between the surface protection film and the mold resin cannot be ensured, the mold resin is separated from the surface protection film by stress caused by heat generation in an operation of the semiconductor device, and reliability of the semiconductor device is reduced. When an upper surface of the surface protection film is roughened, improvement of the adhesiveness between the surface protection film and the mold resin can be expected. However, even when roughening is performed by the sputtering processing as with Patent Document 1, since a maximum surface roughness of the upper surface of the surface protection film is small such as several nanometers to several tens of nanometers, the adhesiveness between the surface protection film and the mold resin cannot be sufficiently increased.

The present disclosure therefore has been made to solve the above problems, and it is an object to provide a semiconductor device capable of increasing adhesiveness between a surface protection film and mold resin.

### Means to Solve the Problem

A semiconductor device according to the present disclosure includes: a semiconductor substrate in which a semiconductor element is formed; a front surface electrode formed on a first main surface of the semiconductor substrate; a back surface electrode formed on a second main surface of the semiconductor substrate; and a surface protection film formed on the first main surface of the semiconductor substrate to cover the front surface electrode and having an opening part exposing a part of the front surface electrode, wherein an upper surface of the surface protection film is roughened by a cutting mark.

### Effects of the Invention

According to the present disclosure, a maximum surface roughness of the upper surface of the surface protection film can be increased. Thus, when the semiconductor device is sealed with mold resin, adhesiveness between the surface protection film and the mold resin can be increased, and such a configuration can contribute to increase of reliability of the semiconductor device.

These and other objects, features, aspects and advantages of the present disclosure will become more apparent from the following detailed description of the present disclosure when taken in conjunction with the accompanying drawings.

### BRIEF DESCRIPTION OF DRAWINGS

FIG. 1 is a cross-sectional view illustrating a configuration of a semiconductor device according to an embodiment 1.

FIG. 2 is a cross-sectional view illustrating a configuration of a semiconductor device according to an embodiment 2.

FIG. 3 is a process diagram illustrating a method of manufacturing a semiconductor device according to an embodiment 3.

FIG. 4 is a process diagram illustrating the method of manufacturing the semiconductor device according to the embodiment 3.

FIG. 5 is a process diagram illustrating the method of manufacturing the semiconductor device according to the embodiment 3.

FIG. 6 is a process diagram illustrating the method of manufacturing the semiconductor device according to the embodiment 3.

FIG. 7 is a process diagram illustrating the method of manufacturing the semiconductor device according to the embodiment 3.

FIG. 8 is a process diagram illustrating the method of manufacturing the semiconductor device according to the embodiment 3.

### DESCRIPTION OF EMBODIMENT(S)

### Embodiment 1

FIG. 1 is a cross-sectional view illustrating a configuration of a semiconductor device 1 according to an embodiment 1.

The semiconductor device 1 includes a semiconductor substrate 2 in which a semiconductor element is formed. Herein, a surface on an upper side of the semiconductor substrate 2 in FIG. 1 is defined as “a first main surface”, a surface on a lower side thereof is defined as “a second main surface”.

A material of the semiconductor substrate 2 may be silicon (Si) and wide bandgap semiconductor such as silicon carbide (SiC) and gallium nitride (GaN). When the wide bandgap semiconductor is used as the material of the semiconductor substrate 2, characteristics excellent in an operation under high voltage, large current, and high temperature is obtained compared with a case of a semiconductor device using silicon. There is no limitation on a type of the semiconductor element formed in the semiconductor substrate 2. When the semiconductor device 1 is a semiconductor device for controlling electrical power, formed in the semiconductor substrate 2 is a power element such as a metal-oxide-semiconductor field-effect transistor (MOSFET), an insulated gate bipolar transistor (IGBT), a Schottky barrier diode (SBD), and a PN junction diode (PND).

Described in the present embodiment is an example that a PN junction diode as a vertical power element is formed in the semiconductor substrate 2. In this case, as illustrated in FIG. 1, a P-type anode region 3 is formed on a surface part of the N-type semiconductor substrate 2 on a side of the first main surface, and an N-type region below the anode region 3 serves as a cathode region 4. The anode region 3 contains a P-type impurity (boron (B), for example) with a high concentration, and the cathode region 4 contains an N-type impurity (phosphorus (P), for example) with a high concentration.

A front surface electrode 5 as an anode electrode is formed on the first main surface of the semiconductor substrate 2, and a back surface electrode 6 as a cathode electrode is formed on the second main surface of the semiconductor substrate 2. A surface protection film 7 made up of thermoset resin such as polyimide is formed on the first main surface of the semiconductor substrate 2 to cover the front surface electrode 5. A opening part exposing a part of the front surface electrode 5 is formed in the surface protection film 7, and wiring, for example, can be connected to the front surface electrode 5 through the opening part.

As illustrated in FIG. 1, the semiconductor device 1 is sealed with mold resin 8. Epoxy resin or polyimide resin, for example, is applied to a material of the mold resin 8.

Herein, cutting processing is performed on the upper surface of the surface protection film 7 using a cutting machine, and the upper surface thereof is roughened by a cutting mark by the cutting processing. Roughening processing by the cutting processing can increase roughness of the upper surface of the surface protection film 7 compared with roughening processing by the sputtering processing disclosed in Patent Document 1 described above. In the present embodiment, a maximum surface roughness of the upper surface of the surface protection film 7 is adjusted to be equal to or larger than 100 nm. In this manner, high adhesiveness is obtained between the surface protection film 7 having such a large maximum surface roughness of the upper surface and the mold resin 8 by anchor effect.

Although details are described hereinafter, a protection film corresponding to the surface protection film 7 is provided to protect the front surface (the first main surface) of the semiconductor substrate 2 in processing the back surface (the second main surface) of the semiconductor substrate in a conventional semiconductor device, and is removed in shipping a product.

According to the semiconductor device 1 in the embodiment 1, high adhesiveness is obtained between the mold resin 8 and the surface protection film 7, and avoided accordingly is separation of the mold resin 8 from the surface protection film 7 by stress caused by heat generation in the semiconductor device 1, and reliability of the semiconductor device is increased.

The above effect is particularly effective when the semiconductor substrate 2 is the wide bandgap semiconductor by reason that the semiconductor device 1 is assumed to be operated in high temperature. Since thermal stress occurring in a case where the semiconductor substrate 2 is made of silicon carbide is significantly larger than a case where the semiconductor substrate 2 is made of silicon as a general semiconductor material, the above effect is significantly effective in the case where the semiconductor substrate 2 is made of silicon carbide.

### Embodiment 2

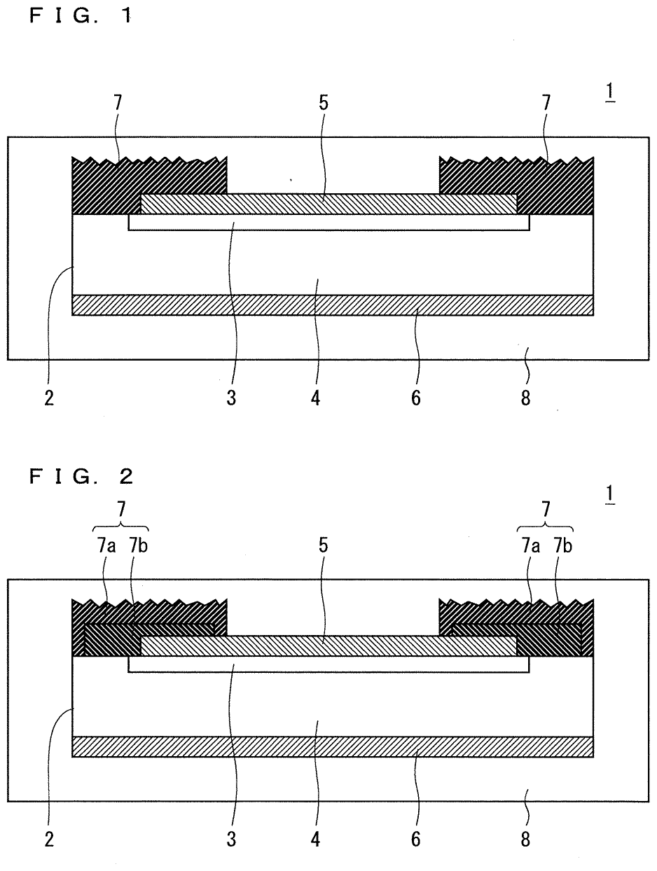

FIG. 2 is a cross-sectional view illustrating a configuration of the semiconductor device 1 according to an embodiment 2. As illustrated in FIG. 2, the surface protection film 7 is made up of a first protection film 7a and a second protection film 7b in the embodiment 2. The other configuration thereof is similar to that of the embodiment 1 (FIG. 1).

The first protection film 7a is an upper layer part of the surface protection film 7, and an upper surface thereof is roughened by a cutting mark. The second protection film 7b is a lower layer part of the surface protection film 7, and intervenes between the first protection film 7a and the semiconductor substrate 2. The first protection film 7a and the second protection film 7b are made up of thermoset resin such as polyimide. However, a material of each of the first protection film 7a and the second protection film 7b is selected so that a thermal expansion coefficient of the second protection film 7b has a value between a thermal expansion coefficient of the first protection film 7a and a thermal expansion coefficient of the semiconductor substrate 2. Since a thermal expansion coefficient of silicon or silicon carbide as a material of the semiconductor substrate 2 is smaller than that of polyimide, for example, the thermal expansion coefficient of the first protection film 7a is set to 80 ppm/K, and the thermal expansion coefficient of the second protection film 7b is set to 50 ppm/K, for example.

When the thermal expansion coefficient of the surface protection film 7 and the thermal expansion coefficient of the semiconductor substrate 2 are significantly different from each other, a crack or separation may occur at an interface between the surface protection film 7 and the semiconductor substrate 2 by stress caused by heat generation in the semiconductor device 1. In the present embodiment, the second protection film 7b having the thermal expansion coefficient relatively close to the semiconductor substrate 2 is located in a part where the surface protection film 7 has contact with the semiconductor substrate 2; thus, stress occurring between the surface protection film 7 and the semiconductor substrate 2 can be reduced.

### Embodiment 3

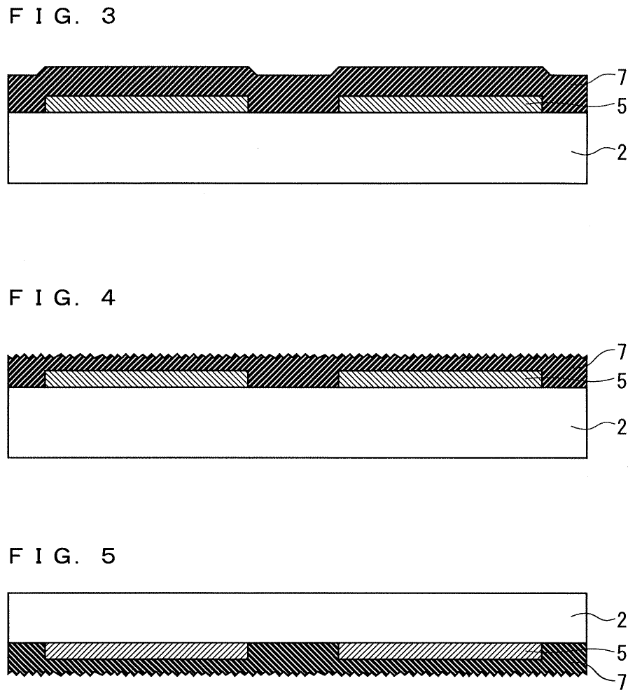

Described in an embodiment 3 is a method of manufacturing the semiconductor device 1 described in the embodiments 1 and 2. FIG. 3 to FIG. 8 are process diagrams for explaining the manufacturing process thereof.

Firstly, a semiconductor element (not shown in FIG. 3 to FIG. 8) such as a PN junction diode is formed in the semiconductor substrate 2, and the front surface electrode 5 is formed on the first main surface of the semiconductor substrate 2.

Next, as illustrated in FIG. 3, the surface protection film 7 covering the front surface electrode 5 is formed on the first main surface of the semiconductor substrate 2. When the semiconductor device 1 according to the embodiment 2 is formed, the surface protection film 7 has a double layer structure of the first protection film 7a and the second protection film 7b.

Then, the upper surface of the surface protection film 7 is cut by a cutting machine, and is roughened by a cutting mark while large unevenness (unevenness corresponding to a shape of the front surface electrode 5) on the upper surface of the surface protection film 7 is flattened. Thermal processing for curing the surface protection film may be performed after the cutting processing.

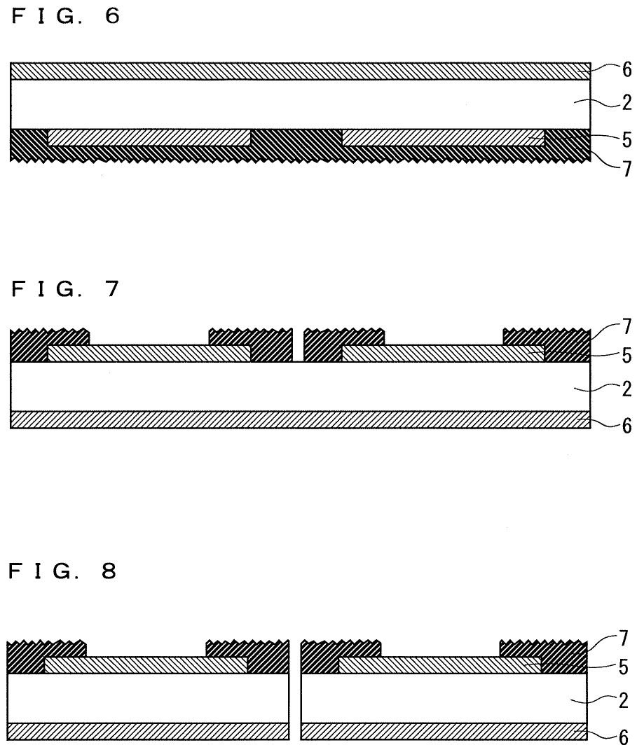

Subsequently, as illustrated in FIG. 5, the semiconductor substrate 2 is turned back while the first main surface of the semiconductor substrate 2 is covered by the surface protection film 7, and the second main surface of the semiconductor substrate 2 is processed. In this process, the semiconductor substrate 2 is thinned by grinding the second main surface and impurity is implanted into the second main surface, for example. As illustrated in FIG. 6, the back surface electrode 6 is formed on the second main surface of the semiconductor substrate 2 while the first main surface of the semiconductor substrate 2 is covered by the surface protection film 7. In this manner, a side of the second main surface of the semiconductor substrate 2 is processed while the first main surface thereof is covered by the surface protection film 7. Thus, the surface protection film 7 also has a role to protect a structure on the side of the first main surface of the semiconductor substrate 2 in processing the side of the second main surface of the semiconductor substrate 2.

Subsequently, as illustrated in FIG. 7, the semiconductor substrate 2 is turned back again and a part of the surface protection film 7 is removed, thereby forming the opening part exposing a part of the front surface electrode 5 in the surface protection film 7. Then, as illustrated in FIG. 8, the semiconductor substrate 2 is cut and divided to form a chip of the semiconductor device 1.

Finally, the semiconductor device 1 is sealed with the mold resin 8 to obtain the configuration of the semiconductor device 1 illustrated in FIG. 1 or FIG. 2.

In the method of manufacturing the semiconductor device 1 according to the present embodiment, the surface protection film 7 has a useful role as a protection film protecting the structure on the side of the first main surface of the semiconductor substrate 2 in processing the side of the second main surface of the semiconductor substrate 2. As described above, although the protection film corresponding to the surface protection film 7 in the conventional semiconductor device is removed in shipping the product, the surface protection film 7 is left in the semiconductor device 1 after being manufactured in the present embodiment. Thus, cost can be reduced by reducing the number of processes. The upper surface of the surface protection film 7 is processed by the cutting processing using the cutting machine; thus, the maximum surface roughness of the upper surface of the surface protection film 7 can be adjusted without adding the other process.

Each embodiment can be arbitrarily combined, or each embodiment can be appropriately varied or omitted.

The foregoing description is in all aspects illustrative, and it is therefore understood that numerous modifications not exemplified can be devised.

### EXPLANATION OF REFERENCE SIGNS

1 semiconductor device, 2 semiconductor substrate, 3 anode region, 4 cathode region, 5 front surface electrode, 6 back surface electrode, 7 surface protection film, 7a first protection film, 7b second protection film, 8 mold resin.

1. A semiconductor device, comprising:
a semiconductor substrate in which a semiconductor element is formed;
a front surface electrode formed on a first main surface of the semiconductor substrate;
a back surface electrode formed on a second main surface of the semiconductor substrate; and
a surface protection film formed on the first main surface of the semiconductor substrate to cover the front surface electrode and having an opening part exposing a part of the front surface electrode, wherein
an upper surface of the surface protection film is roughened by a cutting mark.

2. The semiconductor device according to claim 1, wherein
a maximum surface roughness of the upper surface of the surface protection film is equal to or larger than 100 nm.

3. The semiconductor device according to claim 1, wherein
the surface protection film is made up of thermoset resin.

4. The semiconductor device according to claim 1, wherein
the surface protection film includes a first protection film with an upper surface roughened by the cutting mark and a second protection film intervening between the first protection film and the semiconductor substrate, and
a thermal expansion coefficient of the second protection film has a value between a thermal expansion coefficient of the first protection film and a thermal expansion coefficient of the semiconductor substrate.

5. The semiconductor device according claim 1, wherein
the semiconductor substrate is made up of wide bandgap semiconductor.

6. A method of manufacturing a semiconductor device, comprising:
forming a semiconductor element in a semiconductor substrate;
forming a front surface electrode on a first main surface of the semiconductor substrate;
forming a surface protection film covering the front surface electrode on the first main surface of the semiconductor substrate;
cutting an upper surface of the surface protection film to roughen the upper surface of the surface protection film by a cutting mark;
forming a back surface electrode on a second main surface of the semiconductor substrate while the first main surface of the semiconductor substrate is covered by the surface protection film;
forming an opening part exposing a part of the front surface electrode in the surface protection film after forming the back surface electrode; and
cutting and dividing the semiconductor substrate, thereby forming a chip of a semiconductor device.

7. The semiconductor device according to claim 2, wherein
the surface protection film is made up of thermoset resin.

8. The semiconductor device according to claim 2, wherein
the surface protection film includes a first protection film with an upper surface roughened by the cutting mark and a second protection film intervening between the first protection film and the semiconductor substrate, and
a thermal expansion coefficient of the second protection film has a value between a thermal expansion coefficient of the first protection film and a thermal expansion coefficient of the semiconductor substrate.

9. The semiconductor device according to claim 3, wherein
the surface protection film includes a first protection film with an upper surface roughened by the cutting mark and a second protection film intervening between the first protection film and the semiconductor substrate, and
a thermal expansion coefficient of the second protection film has a value between a thermal expansion coefficient of the first protection film and a thermal expansion coefficient of the semiconductor substrate.

10. The semiconductor device according to claim 7, wherein
the surface protection film includes a first protection film with an upper surface roughened by the cutting mark and a second protection film intervening between the first protection film and the semiconductor substrate, and
a thermal expansion coefficient of the second protection film has a value between a thermal expansion coefficient of the first protection film and a thermal expansion coefficient of the semiconductor substrate.

11. The semiconductor device according to claim 2, wherein
the semiconductor substrate is made up of wide bandgap semiconductor.

12. The semiconductor device according to claim 3, wherein
the semiconductor substrate is made up of wide bandgap semiconductor.

13. The semiconductor device according to claim 4, wherein
the semiconductor substrate is made up of wide bandgap semiconductor.

14. The semiconductor device according to claim 7, wherein
the semiconductor substrate is made up of wide bandgap semiconductor.

15. The semiconductor device according to claim 8, wherein
the semiconductor substrate is made up of wide bandgap semiconductor.

16. The semiconductor device according to claim 9, wherein
the semiconductor substrate is made up of wide bandgap semiconductor.

17. The semiconductor device according to claim 10, wherein
the semiconductor substrate is made up of wide bandgap semiconductor.
